(19) United States
(12) Patent Application Publication
(10) Pub. No.: US 2013/0258443 A1
(43) Pub. Date: Oct. 3, 2013

(54) PIXEL STRUCTURE FOR ELECTROWETTING DISPLAY DEVICES AND METHOD OF MANUFACTURING THE SAME

(71) Applicant: SAMSUNG DISPLAY CO., LTD, Yongin-City (KR)

(72) Inventors: Kwang-Chul JUNG, Seongnam-si (KR); Mee-Hye JUNG, Suwon-si (KR)

(73) Assignee: Samsung Display Co., Ltd, Yongin-City (KR)

(21) Appl. No.: 13/852,546

(22) Filed: Mar. 28, 2013

(30) Foreign Application Priority Data
Mar. 29, 2012 (KR) 10-2012-0032292

(51) Int. Cl. G02B 26/00; H01L 29/66

(52) U.S. Cl. CPC G02B 26/005; H01L 29/66742
USPC 359/290; 438/34

(57) ABSTRACT

An electrowetting display device includes a first display substrate, a second display substrate and a plurality of pixels having a fluid layer disposed between the first and second display substrates. Each of the pixels has a pixel structure including at least one conductive layer having a star-shape or a fan-shape disposed at a center portion of the pixels insulated by an insulating material inside the first display substrate.

### CROSS-REFERENCE TO RELATED APPLICATION

This application claims priority to Korean Patent Application Ser. No. 10-2012-0032292 filed on Mar. 29, 2012, the disclosure of which is hereby incorporated by reference herein in its entirety.

### TECHNICAL FIELD

The present disclosure relates to a pixel structure for use in electrowetting display devices and a method for manufacturing the same, and more particularly to a pixel structure capable of increasing their response rate and a method for manufacturing the same.

### DISCUSSION OF THE RELATED ART

An electrowetting effect refers to the change of contact angle between a conductive hydrophobic fluid and a hydrophobic layer, which is positioned beneath the fluid, as the voltage applied to the fluid varies. Specifically, the smaller the voltage applied to the hydrophobic fluid is, the smaller the contact angle between the hydrophobic fluid and the hydrophobic layer becomes. The smaller the contact angle is, in turn, the larger the area of distribution of the hydrophobic fluid over the hydrophobic layer becomes.

An electrowetting display device is based on such an electrowetting effect.

When a voltage is applied to the pixel of an electrowetting display device, the hydrophobic fluid moves towards the wall, and light is transmitted accordingly, expressing images. When the voltage applied to the pixel electrode is removed, the movement of the hydrophobic fluid, i.e. forming a hydrophobic layer, which prevents transmission of light, does not proceed properly. Specifically, the influence of the inner-pixel notch portion, the stepped portion, and the storage capacitor portion interferes with smooth movement of the hydrophobic fluid, and a black spot, which is generated by absence of movement of the hydrophobic fluid, is more severe when the voltage is removed than when the voltage is applied. Such voltage application and control cause on/off hysteresis. Therefore, there is a need for a pixel structure which allows hydrophobic and hydrophilic fluids to operate rapidly in a short time on the substrate.

### SUMMARY OF THE INVENTION

Exemplary embodiments of the present invention provide a pixel structure of an electrowetting display device having a fast response rate and a method for manufacturing the same.

Further, exemplary embodiments of the present invention provide an electrowetting display device generating no on/off hysteresis and thus having good reliability.

In accordance with an exemplary embodiment of the present invention, there is provided an electrowetting display device. The electrowetting display device includes a first display substrate, a second display substrate, a pixel structure having a of plurality of pixels having a fluid layer disposed between the first and second display substrates. Each of the pixels has a pixel structure including at least one conductive layer having a star-shape or a fan-shape disposed at a center portion of the pixels insulated by an insulating material inside the first display substrate.

In an embodiment, at least one of the pixels includes a first pixel electrodedisposed on the insulating material inside the first display substrate.

In an embodiment, a plurality of conductive layers extend in different radial directions.

In an embodiment, an end of each of the plurality of conductive layers are connected to each other.

In an embodiment, the first pixel electrode has a substantially quadrangular shape, and the first pixel electrode has a corner removed to form chamfer portions.

In an embodiment, at least a part of the chamfer portions has one of a straight shape, a concave shape, or a convex shape.

In an embodiment, the pixel includes a first pixel electrode and a notch portion positioned at a center of the first pixel electrode, and the first pixel electrode and the notch portion are spaced apart from each other.

In an embodiment, a color filter is formed between the first pixel electrode and the first display substrate.

In an embodiment, a through-hole is formed between the conductive layers, and the notch portion and a storage capacitor electrode are connected via the through-hole.

In an embodiment, the first pixel electrode is made of reflective metal.

In an embodiment, a TFT is formed between the first substrate and the first pixel electrode.

In an embodiment, the TFT is connected to a data line extending in a first direction and to a gate line extending in a second direction perpendicular to the first direction, and a center of the first pixel electrode and the TFT are arranged on a straight line parallel with the data line.

In accordance with an exemplary embodiment of the present invention, an electrowetting display device is provided. The electrowetting display device includes a first display substrate including a first base substrate and pixel unit disposed on the first base substrate.

The pixel unit has a pixel structure including a gate line extending adjacent to and parallel with a lower portion of the pixel unit and having a protrusion, a storage capacitor first electrode spaced apart from the gate line, in which the storage capacitor first electrode has an electrode which has a plurality of branches extending radially from a center of the pixel unit, a first insulating layer disposed on the gate line including the protrusion and on the storage capacitor first electrode, a data line disposed on the first insulating layer, in which the data line is adjacent to and parallel with a corner of the pixel unit and perpendicular to the gate line, a source electrode disposed on the first insulating layer and the active layer and protruding from the data line along the gate line, a drain electrode disposed on the active layer and spaced apart from the source electrode, a storage capacitor second electrode disposed on the storage capacitor first electrode with the first insulating layer interposed therebetween, in which the drain electrode has an end connected to the storage capacitor second electrode and in which the storage capacitor second electrode includes an electrode having a plurality of radially extending branches which are connected to one another.

The pixel structure of the pixel unit further includes a second insulating layer covering the source electrode and the drain electrode, an organic film disposed on the second insulating layer, a first contact hole disposed in the second insulating layer and the organic film exposing a surface of the drain electrode, a second contact hole disposed in the first insulating layer, the second insulating layer and the organic film exposing a surface of the storage capacitor first electrode, a pixel electrode disposed on an upper surface of the organic film and electrically connected to the drain electrode through the first contact hole, an isolation electrode disposed on the upper surface of the organic film and electrically connected to the storage capacitor first electrode through the second contact hole and in which the isolation electrode is electrically separated from the pixel electrode, a third insulating layer disposed on the pixel electrode and the isolation electrode, a water repellant layer disposed on the third insulating layer, and a plurality of walls disposed on the water repellant layer at corners of the pixel unit.

The electrowetting display device further includes a second display substrate including a second base substrate facing the first display substrate and a fluid layer filing a space between the first and second display substrates.

In accordance with an exemplary embodiment of the present invention, a method for manufacturing an electrowetting display device is provided. The method includes forming a gate line, a storage capacitor first electrode and a first insulating layer on a first base substrate of a first display substrate, and the storage capacitor first electrode includes an electrode having a plurality of radially extending branches, forming an active layer on the first insulating layer and the gate line, forming a data line, a source electrode, a drain electrode and a storage capacitor second electrode on the first insulating layer and the active layer. The storage capacitor second electrode includes an electrode having a plurality of radially extending branches.

The method further includes forming a second insulating layer on the first base substrate including on the data line, forming an organic film on the second insulating layer, partially removing the second insulating layer and the organic film from the first base substrate to form a first contact hole which exposes the drain electrode, partially removing the first insulating layer, the second insulating layer and the organic film from the first base substrate to form a second contact hole which exposes the storage capacitor first electrode, forming a conductive layer on the drain electrode, lateral walls of the first and second contact holes, an upper surface of the organic film, and on the storage capacitor first electrode, removing a portion of the conductive layer disposed on the upper surface of the organic film to thereby form a pixel electrode on the upper surface of the organic film which is electrically connected to the drain electrode through the first contact hole, an isolation electrode on the upper surface of the organic film which is electrically connected to the storage capacitor first electrode through the second contact hole, and a separation area defined in between the pixel electrode and the isolation electrode on the upper surface of the organic film which electrically separates the pixel electrode and the isolation electrode from each other.

In addition, the method further includes forming a third insulating layer on the first base substrate including on the pixel electrode and the isolation electrode, forming a water-repellant layer on the third insulating layer, forming a plurality of walls on the water-repellant layer and providing a second display substrate including a second base substrate disposed facing the first display substrate.

### BRIEF DESCRIPTION OF THE DRAWINGS

Exemplary embodiments of the present invention can be understood in more detail from the following detailed description taken in conjunction with the accompanying drawings, in which:

FIGS. 1A and 1B illustrate a general structure of an electrowetting display device;

FIG. 2 is a top view of a first display substrate according to an embodiment of the present invention;

FIG. 3 is a sectional view of an electrowetting display panel taken along line of FIG. 2, including the first display substrate;

FIGS. 4(A)-(F) are sectional views illustrating a method for manufacturing the first display substrate and the second display substrate of FIG. 2;

FIG. 5 illustrates an equivalent circuit of each pixel structure shown in FIGS. 2 and 3;

FIGS. 6A-6E and 7A-E are top views illustrating a fluid movement path according to an embodiment the present invention; and

FIG. 8 illustrates a modified shape according to an embodiment of the present invention.

### DETAILED DESCRIPTION OF EXEMPLARY EMBODIMENTS

Hereinafter, exemplary embodiments of the present invention will be described with reference to the accompanying drawings in detail.

It will be understood that when an element or layer is referred to as being “on”, “connected to” or “coupled to” another element or layer, it can be directly on, connected or coupled to the other element or layer or intervening elements or layers may be present.

As used herein, the singular forms, “a”, “an” and “the” are intended to include the plural forms as well, unless the context clearly indicates otherwise. As used herein, the term “and/or” includes any and all combinations of one or more of the associated listed items.

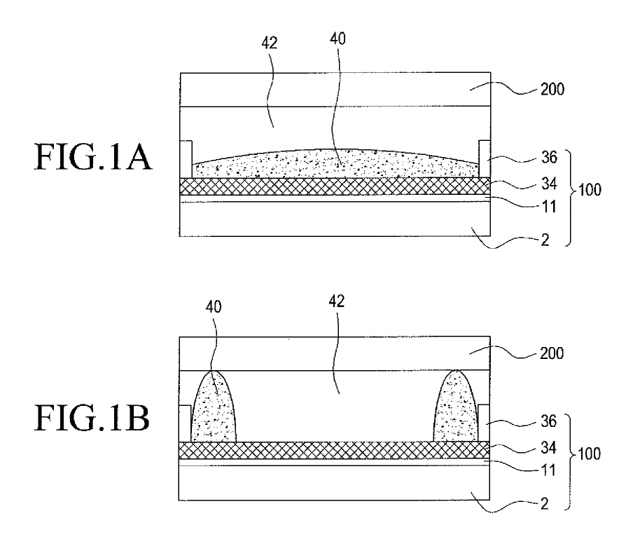

FIGS. 1A and 1B are magnified sectional views of a schematic pixel of an electrowetting display device. The electrowetting display device includes a first display substrate 100, a hydrophobic fluid 40 positioned on the first display substrate 100, a hydrophilic fluid 42 positioned on the hydrophobic fluid 40 without mixing with the hydrophobic fluid 40, and a second display substrate 200 sealed together with the first display substrate 100 while interposing the hydrophobic and hydrophilic fluids 40 and 42. The first display substrate 100 includes a first base substrate 2, a pixel electrode 11 formed on the first base substrate 2, and a water-repellent layer 34 formed on the pixel electrode 11. Walls 36 are formed on the water-repellent layer 34 to limit movement of the hydrophobic fluid 40.

The hydrophobic fluid 40 is a pigment of a predetermined color and, when no voltage is applied to the pixel electrode 11, is distributed over the entire water-repellent layer 34 as shown in FIG. 1(A). When the hydrophobic fluid 40 is a black pigment, for example, light incident into the pixel from outside the first display substrate 100 cannot pass through the hydrophobic fluid 40, so that the pixel is observed as black. When a voltage is applied to the pixel, as shown in FIG. 1(B), the hydrophobic fluid 40 moves towards the hydrophilic wall 36 in proportion to the voltage value applied to the pixel electrode 11. In this case, the area of distribution of the black hydrophobic fluid 40 on the water-repellent layer 34 varies depending on the voltage value applied to the pixel.

The first base substrate 2 may be, for example, a flexible substrate or a rigid substrate. For example, the first base substrate 2 may include flexible substrates made of glass, plastic, or a glass fiber reinforced plastic (FRP).

In addition, the pixel electrode 11 may include, for example, a transparent conductive material such as ITO (indium tin oxide), IZO (indium zinc oxide), aluminum zinc oxide (AZO), or cadmium tin oxide (CTO). Alternatively, the pixel electrode 11 may include, for example, a reflective electric conductor such as aluminum (Al), gold (Au), silver (Ag), copper (Cu), iron (Fe), titanium (Ti), tantalum (Ta), molybdenum (Mo), rubidium (Rb), tungsten (W), and alloys, or combinations thereof.

Moreover, the water-repellant layer 34 may include, for example, amorphous fluoropolymers such as copolymers of tetrafluoroethylene (TFE) and perfluro-2,2 dimethyl 1,3 dioxide (PDD), sold under the brand name TEFLON® AF 1600 which is a registered trademark of the E.I. DuPont de Nemours and Company Corporation, 101 West 10th St., Wilmington, Del. 19898). Alternatively, other low surface energy polymers such as, for example, parylene may be used to form the water repellant layer 34.

The walls 36 may include, for example, a positive photoresist, a negative photoresist, a photoset resin or a thermoset resin.

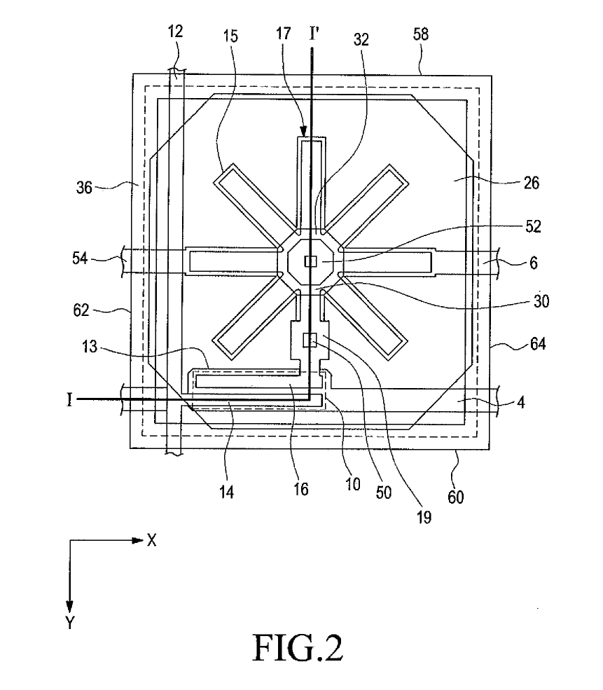

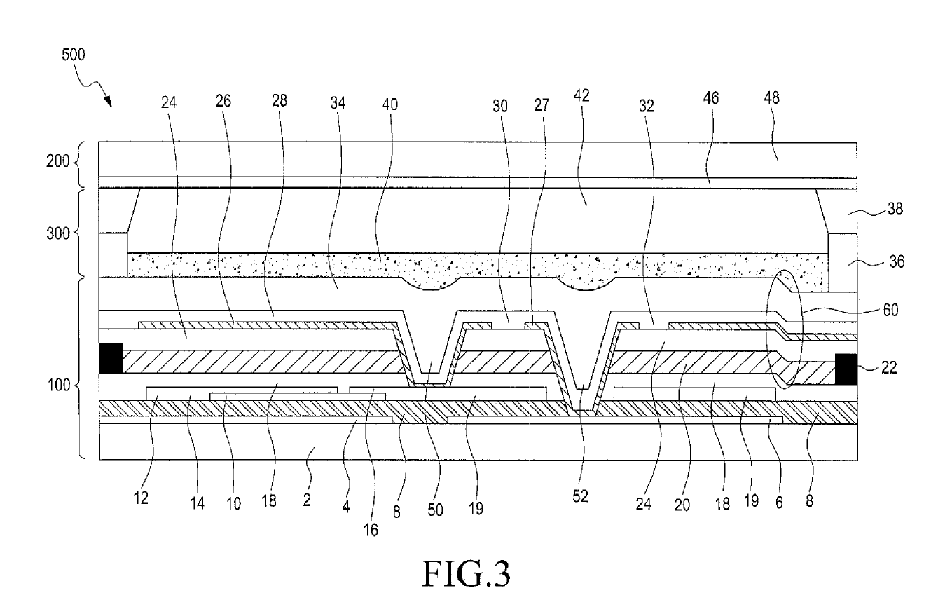

FIG. 2 is a top view of a first display substrate according to an embodiment of a pixel for use in an electrowetting display panel of the present invention. FIG. 3 is a sectional view taken along line I-I′ of FIG. 2, including the first display substrate. Those skilled in the art can understand that, although a single pixel is shown in FIGS. 2 and 3, the electrowetting display panel has a number of pixels arranged in rows and columns. Furthermore, the pixel is shown to have a square shape, but the shape is not limited thereto, and a different shape is possible. However, in the present embodiment, each pixel has a square shape.

Referring to FIGS. 2 and 3, each pixel of the electrowetting display device 500 includes, for example, a first display substrate 100, a second display or upper substrate 200 facing the first display or lower substrate 100, and a fluid layer 300 filling the space between the first and second display substrates 100 and 200.

The first display substrate 100 includes, for example, a first base or lower substrate 2 and a pixel unit formed on the first base substrate 2. The first base substrate 2 may be, for example, a flexible substrate or a rigid substrate. For example, the first base substrate 2 may include flexible substrates made of glass, plastic, or a glass fiber reinforced plastic (FRP).

The pixel unit has, for example, a gate line 4 and a storage capacitor first electrode 6 spaced from the gate line 4, all of which are conductive, and which are formed on the first base substrate 2. The gate line 4 extends, for example, adjacent to and parallel with a lower corner 60 of the pixel, e.g. in the row direction (X direction), and has a protrusion 13. The storage capacitor first electrode 6 is formed, for example, in parallel with the gate line 4 and extends through the center of the pixel.

The storage capacitor first electrode 6 has, for example, a star-shaped electrode 17, which has branches 15 extending radially from the center of the storage capacitor first electrode 6, at the center of each pixel. For example, four branches extend towards the four corners of each pixel, respectively. It is to be noted that, although the star-shaped electrode 17 is shown to have eight branches, the number of branches for the star-shaped electrode 17 of exemplary embodiments of the present invention is not limited thereto. A first insulating layer 8 is formed on the gate line 4 and the storage capacitor first electrode 6.

An active layer 10, which is a semiconductor layer, is formed, for example, on a portion of the first insulating layer 8, disposed on the left end and the protrusion 13 of the gate line 4. The insulating layer 8 is disposed in between the gate line 4 and the active layer 10. A data line 12 is formed, for example, on the first insulating layer 8 to be adjacent to and parallel with the left corner 62 of the pixel unit, and perpendicular to the gate line 4. A source electrode 14 is formed, for example, on the first insulating layer 8 and the semiconductor layer 10, which lies on it, so as to protrude from the data line 12 along the gate line 4. A drain electrode 16 is formed, for example, on the semiconductor layer 10 and is spaced apart from the source electrode 14. Therefore, the source electrode 14, the drain electrode 16, and a channel formed inside the semiconductor layer 10 between them during operation constitute a thin film transistor (TFT). The drain electrode 16 has, for example, an end connected to a storage capacitor second electrode 19 formed on the star-shaped electrode 17 with the first insulating layer 8 interposed. Therefore, the storage capacitor second electrode 19 has, for example, eight radially extending branches, which are connected to one another. The branches are made of, for example, the same material as the drain electrode 16. Therefore, when the TFT is turned on, voltage on the data line 12 is transmitted to the branches. A second insulating layer 18 covers the source electrode 14 and the drain electrode 16. A color filter layer 20 can be formed, for example, on the second insulating layer 18, and black matrixes 22 are formed on the left and right sides of the color filter layer 20. An insulating organic film 24 is formed on the color filter layer 20. A first contact hole 50 is formed, for example, on the second insulating layer 18, the color filter layer 20, and the organic film 24 to expose a surface of the storage capacitor second electrode 19. A second contact hole 52 is formed, for example, on the second insulating layer 18, the color filter layer 20, and the organic film 24 to expose a surface of the storage capacitor first electrode 6. A pixel electrode is formed, for example, on the bottoms and lateral walls of the formed first and second contact holes 50 and 52 and on the organic film 24. However, no pixel electrode is formed on each pixel's four corners and peripheral portions 30 and 32 of the second contact hole 52. Therefore, oil contracts on these portions during pixel operation, as described later. A third insulating layer 28 is formed, for example, globally on the pixel electrode 26 and the peripheral portions 30 and 32, and a water-repellent layer 34 is formed on the third insulating layer 28. Walls 36 are formed, for example, on the water-repellent layer 34 at the corners of each pixel to separate pixels. The above-mentioned formation of the first display substrate 100 is followed by the formation of a second display substrate 200, which will now be described.

The second display substrate 200 includes, for example, a second base substrate 48, a second electrode or common electrode 46 formed beneath it, and spacers 38 positioned along the corners. The second base substrate 48 may be, for example, a flexible substrate or a rigid substrate. For example, the second base substrate 48 may include flexible substrates made of glass, plastic, or a glass fiber reinforced plastic (FRP).

The first and second display substrates 100 and 200 are sealed so that the walls 36 and spacers 38 engage with each other. A fluid layer 300 fills a space between the walls 36, the spacers 38 and the first and second display substrates 100, 200. The fluid layer 300 includes, for example, a hydrophobic fluid 40 and a hydrophilic fluid 42. In an exemplary embodiment, the hydrophobic fluid 40 may include a black dye or pigment. Alternatively in an exemplary embodiment, the hydrophobic fluid 40 may include other dyes or pigments of primary colors such as red, green, cyan, magenta, blue, or yellow.

A method of using each pixel of the electrowetting display device according to the the present exemplary embodiment of the present invention, which has been described with reference to FIGS. 2 and 3, will now be described.

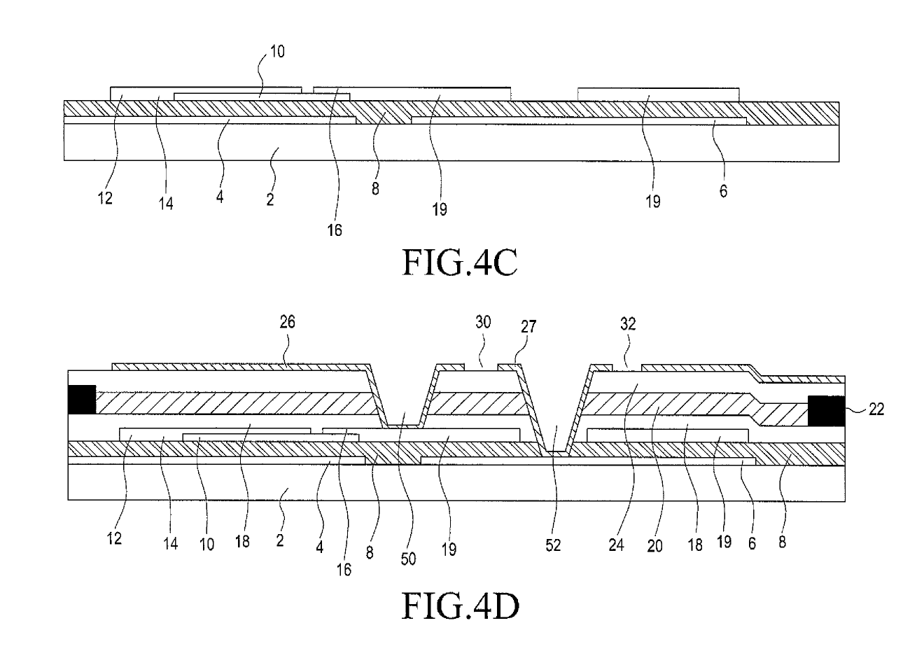

FIG. 5 illustrates an equivalent circuit of each pixel structure shown in FIGS. 2 and 3.

Referring to FIG. 5, the same reference numerals are used as corresponding to those in FIGS. 2 and 3.

A voltage of about 15V is applied to the data line 12, the lower common electrode 54 connected to the storage capacitor first electrode 6, and the upper common electrode 46, and a voltage for tuning the TFT on is applied to the gate line 4. The voltage of about 15V on the data line 12 is applied to the pixel electrode 26 of the electrowetting pixel capacitor 56 (Cew) and the second electrode 19 of the storage capacitor 6 (Cst) through the source electrode 14 channel and the drain electrode 16 of the TFT. Therefore, there is no change of the electric fields between the pixel capacitor 56 and the storage capacitor. As a result, there is no movement or contraction of the fluid, e.g. hydrophobic fluid 40. Consequently, there is no transmission of light coming from outside the first base substrate, and a black color is displayed.

On the other hand, when about −15V is applied to the data line 12, when about 15V is applied to the lower common electrode 54 and the upper common electrode 46, and when the TFT is turned on, the electrowetting pixel capacitor 56, which consists of the pixel electrode 26, the upper common electrode 46, and fluids between them, and the first electrode 6 of the storage capacitor, which consists of the lower common electrode 54, the second electrode 19 of the storage capacitor, and the insulating material between them, have an application field of about 30V. However, the application field of a portion corresponding to the second contact hole 52 is about 0V. Therefore, the hydrophobic fluid 40 on the radially extending branches 15 contracts, e.g.. oil breaking commences. Drops of the application field occur on corners of the branches 15, and the oil contracted by the oil breaking moves to the portions where drops occur and thus to the four corners of the pixel. The second contact hole 52 portion (also referred to as a notch portion) has no drop of application field, and the moving hydrophobic fluid 40 stays on the second contact hole 52 portion. Therefore, exemplary embodiments of the present invention are characterized in that the contracted oil is guided to the four corners of the pixel and the second contact hole 52 through paths defined by the eight radially extending branches 15 and the second contact hole 52 separate from them. It is also beneficial in the present exemplary embodiment of the present invention that it has radially extending branches 15 which guide the contracted oil to the corners of the pixel or the second contact hole 52. Those skilled in the art can readily understand that the number of branches is not limited to eight, as long as there exist guiding corners, on which drops of application field occur. Therefore, this beneficially generates oil breaking points, from which oils move rapidly.

A manufacturing method according to an exemplary embodiment of the present invention will now be described.

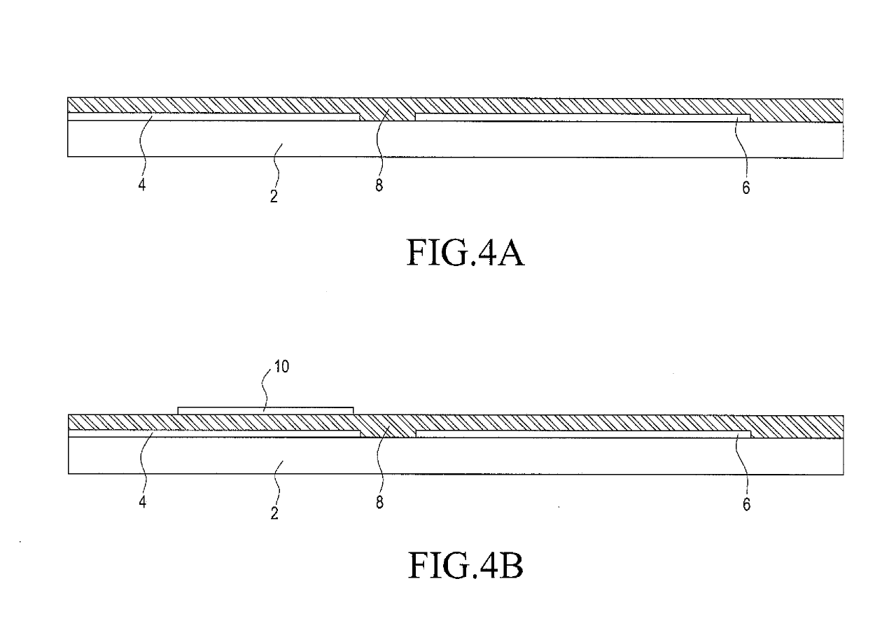

FIGS. 4(A)-(F) are sectional views illustrating a method for manufacturing the first display substrate 100 and second display substrate 200 of FIG. 2.

For example, referring to FIG. 4(A), a gate line 4, a storage capacitor first electrode 6, and a first insulating layer 8 are formed on the base substrate 2. The gate line 4 may be, for example, an Al layer having a thickness of about 1000-5000 Å or a Mo layer having a thickness of about 200-1000 Å. The first insulating layer 8 may be made of, for example, silicon nitride (SiNx) and has a thickness of about 2000-10000 Å. The storage capacitor first electrode 6 may have the shape of, for example, radially extending pins according to the present exemplary embodiment of the present invention.

For example, referring to FIG. 4(B), an active layer 10 is formed on the first insulating layer 8 and the gate line 4. The active layer 10 may be made of, for example, a semiconductor material, such as amorphous silicon (a-Si), and has a thickness of about 2000-10000 Å. The active layer 10 may include a single layer or multiple layers.

For example, referring to FIG. 4(C), a data line 12, a source electrode 14, a drain electrode 16, and a storage capacitor second electrode 19 are formed on the first insulating layer 8 and the active layer 10. The data line 12 may be made of, for example, a metallic material, such as Mo, and has a thickness of about 1000-4000 Å. The data line 12 may include a single layer or multiple layers.

For example, semiconductor patterns and a data metal layer are successively formed on the first insulating layer 8. The semiconductor patterns and the data metal layer are, for example, simultaneously patterned using photolithography technology to form the active layer 10, the source electrode 14, the drain electrode 16, and the storage capacitor second electrode 19 and the data line 12.

Alternatively, for example, a semiconductor layer is formed and patterned to form the active layer 10, the source electrode 14, the drain electrode 16, and the storage capacitor second electrode 19 and a data metal layer is formed on the first base substrate 2, on which the active layer 10, the source electrode 14, the drain electrode 16, and storage capacitor second electrode 19 are formed, and is patterned to form the data line 12.

For example, referring to FIG. 4(D), a second insulating layer 18, a color filter layer 20, black matrixes 22, and an organic film 24 are successively formed on the base substrate 2 on which the data line 12 is formed. The second insulating layer 18 may be made of, for example, a metallic material, such as SiNx, and has a thickness of about 500-2000 Å. The organic film 24 has, for example, a thickness of about 10000-40000 Å. The color filter layer 20 is patterned to form the color filter layer 20 on the first base substrate 2. For example, the color filter is patterned to form a red color filter pattern, a green color filter pattern, and a blue color filter pattern.

Black matrixes 22 are patterned and formed on the second insulating layer 18, on which the color filter layer 20 is formed, to interrupt light, and an organic film 24 is formed on the color filter layer 20.

The second insulating layer 18, the color filter layer 20, and the organic film 24 are, for example, partially removed from the first base substrate 2 by photolithography technology to form a first contact hole 50, which partially exposes the drain electrode 16.

The first insulating layer 8, the second insulating layer 18, the color filter layer 20, and the organic film 24 are, for example, partially removed from the first base substrate 2 using photolithography technology to form a second contact hole 52, which partially exposes the storage capacitor first electrode 6.

After the first and second contact holes 50 and 52 are formed, a conductive electrode layer is, for example, globally formed on the drain electrode 16 and the exposed lateral walls of the first contact hole 50, on the storage capacitor first electrode 6 and the exposed lateral walls of the second contact hole 52, and on the organic film 24. Then, the first pixel electrode 26 and the isolation electrode 27 are separated, for example, by separation areas 30 and 32 using photolithography technology.

The first pixel electrode 26 is electrically connected to the drain electrode 16 through the first contact hole 50, and the isolation electrode 27 is electrically connected to the storage capacitor first electrode 6 through the second contact hole 52. It is to be noted, however, that the first pixel electrode 26 and the isolation electrode 27 are electrically separated.

For example, referring to FIG. 4(E), a third insulating layer 28 and a water-repellent layer 34 are successively formed on the first base substrate 2, on which the first pixel electrode 26 is formed. The third insulating layer 28 is made of, for example, metal, such as silicon nitride (SiNx), and has a thickness of about 500-2000 Å. The water-repellent layer 34 may be made of, for example, amorphous fluoropolymer, and has a thickness of about 200-10000 Å. For example, in an exemplary embodiment, the water-repellant layer 34 may be formed of copolymers of tetrafluoroethylene (TFE) and perfluro-2,2 dimethyl 1,3 dioxide (PDD), sold under the brand name TEFLON® AF 1600 which is a registered trademark of the E.I. DuPont de Nemours and Company Corporation, 101 West 10th St., Wilmington, Del. 19898). Alternatively, other low surface energy polymers such as, for example, parylene may be used to form the water repellant layer 34.

For example, square walls 36 are formed to separate pixels on the water-repellent layer 34. The walls 36 may be made of, for example, negative photoresist, and have a thickness of about 10 μm or less. Alternatively, in an embodiment, the walls 36 may be made of a positive photoresist, a photoset resin or a thermoset resin.

A method for manufacturing the second display substrate, e.g. upper substrate, will now be described.

For example, referring to FIG. 4(F), the second base substrate 48 includes the common electrode 46 and the spacers 38. The spacers 38 are made of, for example, a thick photoresist and have a thickness of about 30 μm or less.

The common electrode 46 is formed, for example, on the second base substrate 48. The spacers 38 are, for example, patterned and formed on the common electrode 46.

The walls 36 and the spacers 38, which are formed on the first and second display substrates 100 and 200 (lower and upper substrates), respectively, are fixed to each other with, for example, the hydrophobic fluid 40 and the hydrophilic fluid 42 filling the space between them.

Although, the present exemplary embodiment describes the first display substrate 100 being formed prior to the second display substrate 200, it is noted that exemplary embodiments of the present invention are not limited thereto. For example, alternatively, in an exemplary embodiment, the second display substrate 200 may be formed prior to the first display substrate 100.

According to the present embodiment, on the first display substrate 100, the first pixel electrode 26 and the drain electrode 16 contact each other through the first contact hole 50, thereby increasing the aperture ratio of the pixel unit.

Furthermore, on the first display substrate 100, the isolation electrode 27 and the storage capacitor first electrode 6 contact each other through the second contact hole 52, thereby increasing the aperture ratio of the pixel unit.

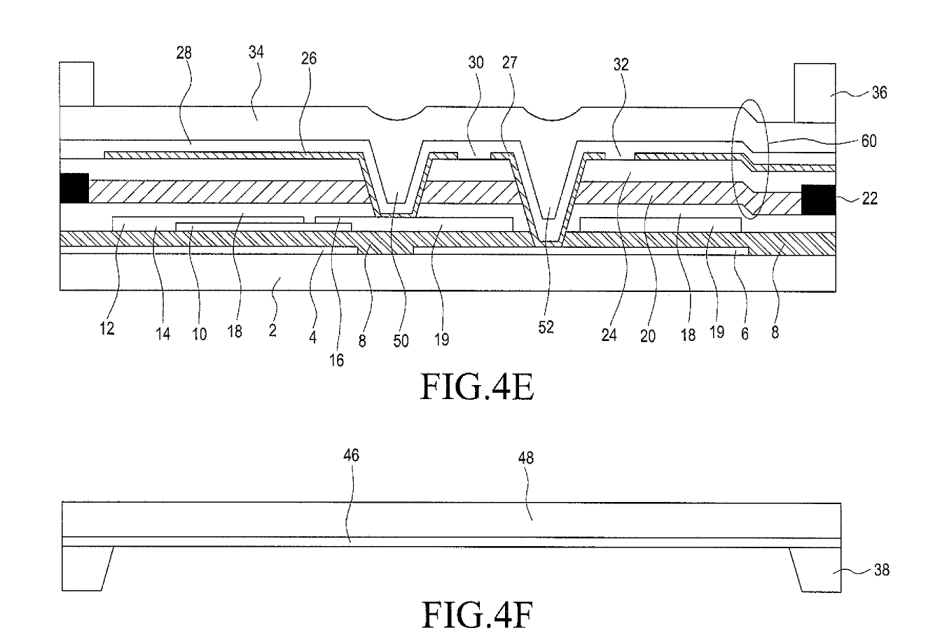

FIGS. 6A-6E illustrate the movement of oil according to an embodiment of the present invention.

For example, referring to FIG. 6(A), the first display substrate according to the present embodiment, as described above, has a plurality of stepped portions 60, which are formed by a star-shaped electrode of the storage capacitor second electrode 19, and which are repeatedly arranged in the same shape about the second contact hole 52.

As described above, when a voltage of about 30V is applied between the first pixel electrode 26 and the common electrode 46 and between the storage capacitor's first electrode 6 and the storage capacitor second electrode 19 including a star-shaped electrode, oil breaking 58 occurs first on the water-repellent layer 34 on the storage capacitor second electrode 19 including the star-shaped electrode, as shown in FIG. 6(B). The hydrophobic fluid 40, which is pushed away by the oil breaking 58, moves towards the stepped portions, as shown in FIG. 6(C), and, as shown in FIGS. 6(D) and 6(E), the moving hydrophobic fluid is guided by the stepped portions towards the four corners. The oil thus guided by the stepped portions moves to the corners rapidly.

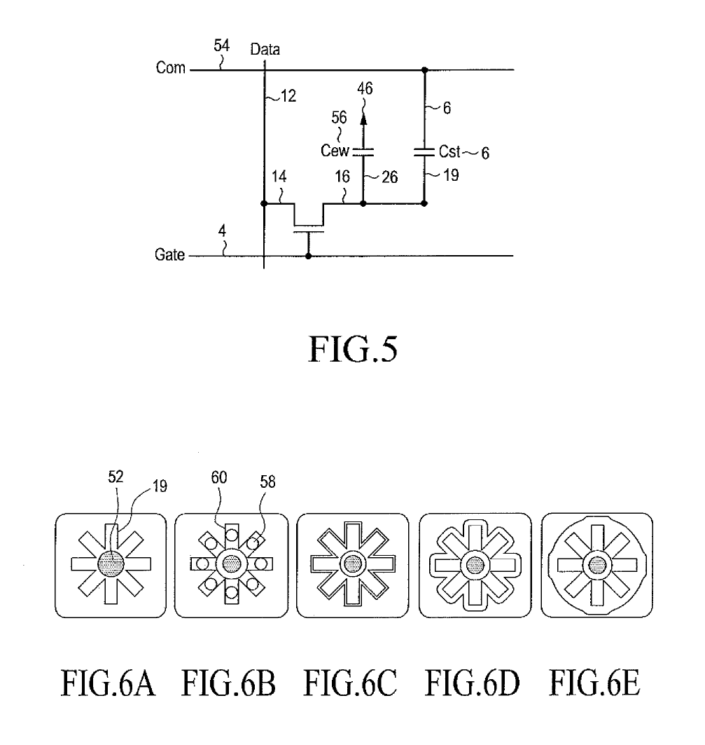

FIG. 7A-E illustrate the movement of oil in accordance with an embodiment of the present invention which is substantially the same as the operation described in connection with FIGS. 6A-E, except that the electrode of the storage capacitor second electrode 19 has a fan shape rather than a star shape.

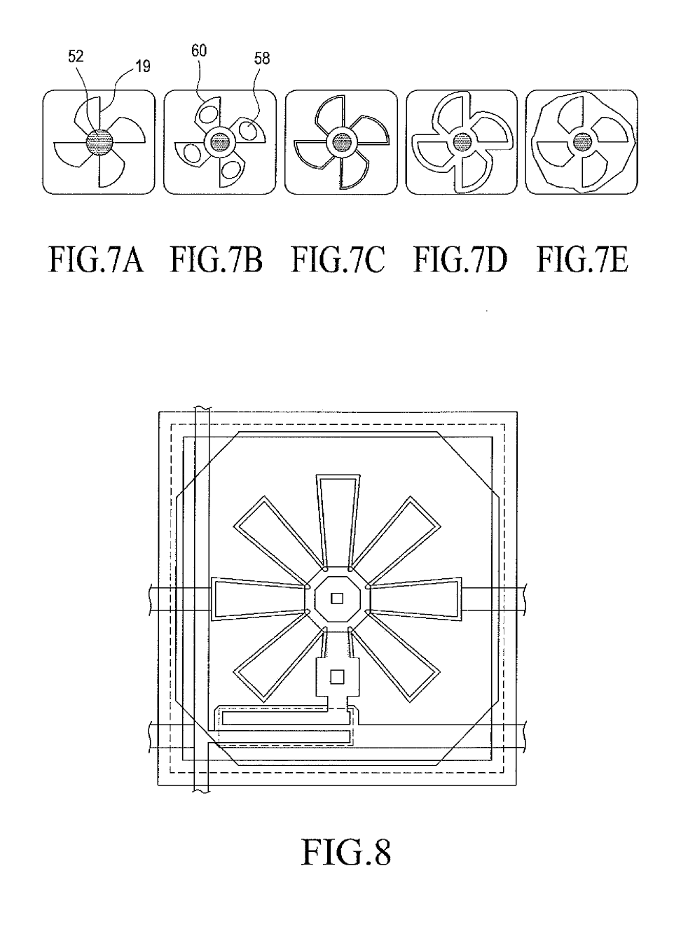

FIG. 8 is similar to the sectional view of FIG. 2, except that the branches of the star shape have a width gradually increasing in the radial direction.

Various modifications can be made according to exemplary embodiments of the present invention. For example, in the description of the present embodiment, the first display substrate 100 includes a color filter layer 20, but exemplary embodiments of the present invention are not limited thereto. For example, alternatively, in an embodiment, the first display substrate 100 may have a transparent organic film 24 instead of the color filter layer 20, and the hydrophobic fluid 40 may be red, green, and blue oils. Alternatively, for example, the first display substrate 100 can include a transparent organic film instead of the color filter layer 20, and the second display substrate 200 can include a color filter layer. Alternatively, for example, the first display substrate 100 may not include the color filter layer 20, the hydrophobic fluid 40 may be red, green, and blue oils, or the second display substrate 200 may include a color filter layer. In an embodiment, in addition to red, blue and green oils, other colored oils may also be used in the hydrophobic fluid 40 such as cyan, magenta, or yellow oils.

Although an embodiment of the present invention has been described with regard to a transmission-type electrowetting display device using no reflective film, e.g. light coming from outside the first base substrate 2 is transmitted, it is also possible to use a reflection-type electrowetting display device having a reflective film formed above or below the pixel electrode to reflect light coming from outside the second base substrate 48.

In addition, the electrowetting display device according to the present exemplary embodiment of the present invention is applicable to, for example, a transparent display, e-paper, a reflection-type DID, etc.

Exemplary embodiments of the present invention are beneficial in that, by using the design of the storage capacity's second electrode 19, a hydrophobic fluid is uniformly distributed over the entire display device. In addition, the hydrophobic fluid moves to the desired position rapidly, substantially increasing the response rate. Other benefits will be readily understood by those skilled in the art from the detailed description of exemplary embodiments of the present invention.

Having described exemplary embodiments of the present invention, it is further noted that it is readily apparent to those of ordinary skill in the art that various modifications may be made without departing from the spirit and scope of the invention which is defined by the metes and bounds of the appended claims.

What is claimed is:

1. An electrowetting display device comprising:
a first display substrate;
a second display substrate; and
a plurality of pixels having a fluid layer disposed between the first and second display substrates, wherein
each of the pixels has a pixel structure comprising at least one conductive layer having a star-shape or a fan-shape disposed at a center portion of the pixels insulated by an insulating material inside the first display substrate.

2. The electrowetting display device as claimed in claim 1, wherein at least one of the pixels comprises a first pixel electrode disposed on the insulating material inside the first display substrate.

3. The electrowetting display device of claim 1, wherein a plurality of conductive layers extend in different radial directions.

4. The electrowetting display device of claim 3, wherein an end of each of the plurality of conductive layers are connected to each other.

5. The electrowetting display device of claim 2, wherein the first pixel electrode has a substantially quadrangular shape, and the first pixel electrode has a corner removed to form chamfer portions.

6. The electrowetting display device of claim 5, wherein at least a part of the chamfer portions has one of a straight shape, a concave shape, or a convex shape.

7. The electrowetting display device of claim 2, wherein the at least one of the pixels comprises a first pixel electrode and a notch portion disposed at a center of the first pixel electrode, and the first pixel electrode and the notch portion are spaced apart from each other.

8. The electrowetting display device of claim 2, wherein a color filter is disposed between the first pixel electrode and the first display substrate.

9. The electrowetting display device of claim 7, wherein the pixel structure includes a plurality of conductive layer and wherein a through-hole is disposed between the conductive layers, and the notch portion and a storage capacitor electrode are connected via the through-hole.

10. The electrowetting display device of claim 2, wherein the first pixel electrode is made of reflective metal.

11. The electrowetting display device of claim 2, wherein a thin film transistor (TFT) is disposed between the first substrate and the first pixel electrode.

12. The electrowetting display device of claim 11, wherein the TFT is connected to a data line extending in a y direction and to a gate line extending in an x direction perpendicular to the y direction, and a center of the first pixel electrode and the TFT are arranged on a straight line parallel with the data line.

13. The electrowetting display device of claim 1, wherein each of the pixels has a pixel structure comprising a star-shaped conductive layer.

14. The electrowetting display device of claim 1, wherein each of the pixels has a pixel structure comprising a fan-shaped conductive layer.

15. An electrowetting display device comprising:
a first display substrate including a first base substrate and a pixel unit disposed on the first base substrate, wherein the pixel unit has a pixel structure comprising:
a gate line extending adjacent to and parallel with a lower portion of the pixel unit and having a protrusion,
a storage capacitor first electrode spaced apart from the gate line, wherein the storage capacitor first electrode has an electrode which has a plurality of branches extending radially from a center of the pixel unit,
a first insulating layer disposed on the gate line including the protrusion and on the storage capacitor first electrode,
a data line disposed on the first insulating layer, wherein the data line is adjacent to and parallel with a corner of the pixel unit and perpendicular to the gate line,
a source electrode disposed on the first insulating layer and the active layer and protruding from the data line along the gate line,
a drain electrode disposed on the active layer and spaced apart from the source electrode,
a storage capacitor second electrode disposed on the storage capacitor first electrode with the first insulating layer interposed therebetween, wherein the drain electrode has an end connected to the storage capacitor second electrode and wherein the storage capacitor second electrode includes an electrode having a plurality of radially extending branches which are connected to one another,
a second insulating layer covering the source electrode and the drain electrode,
an organic film disposed on the second insulating layer,
a first contact hole disposed in the second insulating layer and the organic film exposing a surface of the drain electrode,
a second contact hole disposed in the first insulating layer, the second insulating layer and the organic film exposing a surface of the storage capacitor first electrode,
a pixel electrode disposed on an upper surface of the organic film and electrically connected to the drain electrode through the first contact hole,
an isolation electrode disposed on the upper surface of the organic film and electrically connected to the storage capacitor first electrode through the second contact hole and wherein the isolation electrode is electrically separated from the pixel electrode;
a third insulating layer disposed on the pixel electrode and the isolation electrode,
a water repellant layer disposed on the third insulating layer, and
a plurality of walls disposed on the water repellant layer at corners of the pixel unit;
a second display substrate including a second base substrate facing the first display substrate; and
a fluid layer filing a space between the first and second display substrates.

16. The electrowetting display device of claim 15, further comprising a common electrode disposed under the second display substrate and a plurality of spacers disposed on the common electrode and wherein the spacers engage with the walls disposed on the water repellant layer.

17. The electrowetting display device of claim 15, wherein the fluid layer includes a hydrophilic fluid and a hydrophobic fluid.

18. The electrowetting display device of claim 15, wherein the branches of the electrode of the storage capacitor second electrode include a same material as a material of the drain electrode.

19. The electrowetting display device of claim 15, further comprising:
a color filter layer disposed in between the second insulating layer and the organic film; and
a plurality of black matrixes disposed on the second insulating layer and on sides of the color filter layer.

20. The electrowetting display device of claim 15, wherein the pixel electrode and the isolation electrode are electrically separated from each other by a separation area defined in between the pixel electrode and the isolation electrode on the upper surface of the organic film.

21. The electrowetting display device of claim 15, wherein the electrodes of the storage capacitor first electrode and the storage capacitor second electrode each have a star-shape.

22. A method for manufacturing an electrowetting display device, comprising:
forming a gate line, a storage capacitor first electrode and a first insulating layer on a first base substrate of a first display substrate, wherein the storage capacitor first electrode includes an electrode having a plurality of radially extending branches;
forming an active layer on the first insulating layer and the gate line;
forming a data line, a source electrode, a drain electrode and a storage capacitor second electrode on the first insulating layer and the active layer, wherein the storage capacitor second electrode includes an electrode having a plurality of radially extending branches;
forming a second insulating layer on the first base substrate including on the data line;
forming an organic film on the second insulating layer;
partially removing the second insulating layer and the organic film from the first base substrate to form a first contact hole which exposes the drain electrode;
partially removing the first insulating layer, the second insulating layer and the organic film from the first base substrate to form a second contact hole which exposes the storage capacitor first electrode;
forming a conductive layer on the drain electrode, lateral walls of the first and second contact holes, an upper surface of the organic film, and on the storage capacitor first electrode;
removing a portion of the conductive layer disposed on the upper surface of the organic film to thereby form a pixel electrode on the upper surface of the organic film which is electrically connected to the drain electrode through the first contact hole, an isolation electrode on the upper surface of the organic film which is electrically connected to the storage capacitor first electrode through the second contact hole, and a separation area defined in between the pixel electrode and the isolation electrode on the upper surface of the organic film which electrically separates the pixel electrode and the isolation electrode from each other;
forming a third insulating layer on the first base substrate including on the pixel electrode and the isolation electrode;
forming a water-repellant layer on the third insulating layer;
forming a plurality of walls on the water-repellant layer; and
providing a second display substrate including a second base substrate disposed facing the first display substrate.

23. The method of claim 22, further comprising:
forming a common electrode under the second base substrate and a plurality of spacers on the common electrode; and
fixing the first and second display substrates to each other with a fluid layer filling a space therebetween, and wherein the fluid layer includes a hydrophobic fluid and a hydrophilic fluid.

24. The method of claim 22, wherein the active layer, the source electrode, the drain electrode, the storage capacitor second electrode and the data line are formed on the first insulating layer by successively forming a plurality of semiconductor patterns and a data metal layer on the first insulating layer and wherein the semiconductor patterns and the data metal layer are simultaneously etched to form the active layer, the source electrode, the drain electrode, the storage capacitor second electrode and the data line.

25. The method of claim 22, wherein the electrodes of the storage capacitor first electrode and the storage capacitor second electrode each have a star-shape.
